(19) United States
(12) Patent Application Publication
(10) Pub. No.: US 2018/0219121 A1
(43) Pub. Date: Aug. 2, 2018

(54) Method for the Cryogenic Processing of Solar Cells and Solar Panel Components

(71) Applicant: Peter Paulin, Decatur, IL (US)

(72) Inventor: Peter Paulin, Decatur, IL (US)

(21) Appl. No.: 15/881,915

(22) Filed: Jan. 29, 2018

Related U.S. Application Data
(60) Provisional application No. 62/451,744, filed on Jan. 29, 2017.

(51) Int. Cl. H01L 31/18

(52) U.S. Cl. CPC H01L 31/186

(57) ABSTRACT

A method for cryogenic retreating solar cells and solar cell components in order to decrease resistance and increase photovoltaic output. The method involves placing the solar cells and solar cell components in a cryogenic processor wherein the cells and panel components are lowered to approximately −300° F. This temperature is maintained for a predetermined time, after which the temperature is raised to ambient temperature over time.

### BACKGROUND OF THE INVENTION

### Fields of the Invention

This invention relates to the field of cryogenic processing of metals and more specifically metals and metalloids contained in certain electrical and non-electrical components found in modern solar panels including the solar cells themselves. Monocrystalline silicon is the predominate form of silicon used in solar cells and serves as the light absorbing, photovoltaic (PV) used in the manufacturing process. Monocrystalline silicon may be differentiated from allotropic forms of silicon such as amorphous silicon and polycrystalline silicon used in the production of thin-film solar cells. Compared with polycrystalline and amorphous silicon, the monocrystalline structure is composed of a crystal lattice that is continuous and unbroken due to the absence of grain boundaries. Thus, use of monocrystalline silicon is the preferred medium for solar cells do to its high PV efficiencies.

### Description of the Related Art

To date, the only mechanism of increasing the PV efficiency of monocrystalline silicon was to dope the silicon with very small quantities of other elements. An example of these elements used, for example, in semi-conductors can include dopants of the acceptor type, i.e., Boron, Aluminum, Nitrogen, Gallium and elements of the donor type such as Phosphorus, Arsenic, Antimony and Bismuth.

### Objects and Advantages of the Invention

The present invention provides and unique and innovative mechanism of increasing the efficiency of solar cells of all types whether using doped or un-doped silicon. Since this method is a post manufacturing method, it is much less expensive than the doping process, it can be used and an adjunct to doping to further increase the efficiency of the solar cells or in some applications could be used in place of doping. Further, the method will also have application in increasing the efficiency of allotropic forms of silicones such as amorphous silicones and polycrystalline silicones and inorganic and organic perovskite solar cells containing lead or tin-halide based material. Cryogenic processing has traditionally, its primary application in increasing the wear and corrosion resistance of various metals. Here this invention extends the benefits of cryogenic processing into the realm of metalloids with silicon being the prime example. Testing has indicated the solar cell efficiencies can be increased by an average of 15% by cryogenic treatment. However, using a conservative estimate of a 10% increase in efficiency, and using the number of kWh produced and consumed in the US through photovoltaics, a power consumption savings of a staggering $190,819,200.00 is anticipated.

### BRIEF DESCRIPTION OF THE DRAWINGS

FIG. 1 is a block diagram depicting the steps of the process.

FIG. 2 is a typical temperature profile showing the various temperature stages of the

process.

### DESCRIPTION OF A PREFERRED EMBODIMENT

This method involves the cryogenic treatment of solar cells and solar cell components through the reduction in their temperature within a cryogenic processor in accordance with a programmed reduction, maintenance and elevation of temperature over predetermined time periods. These programed reductions are termed thermal profiles and may vary with the type of material being cryogenically treated. Thus, this preferred embodiment is not intended to limit the method to precisely those steps discussed herein but are simply utilized to illustrate the principles of the method.

Generally the method herein is for the cryogenic treatment of solar cells and solar panel components which involves the gradual lowering of temperature of the cells and components to approximately −300° F. or lower over a predetermined time. Requirements and then allowed to remain at cryogenic temperatures for a period of time and then the temperature is gradually raised to ambient temperature. The gradual cooling the scent and warming a sent is designed to avoid physical stresses which may damage the cells and components. Cryogenic processors are well known to those skilled in the art, does not add to the novelty of the process and are not described in detail here.

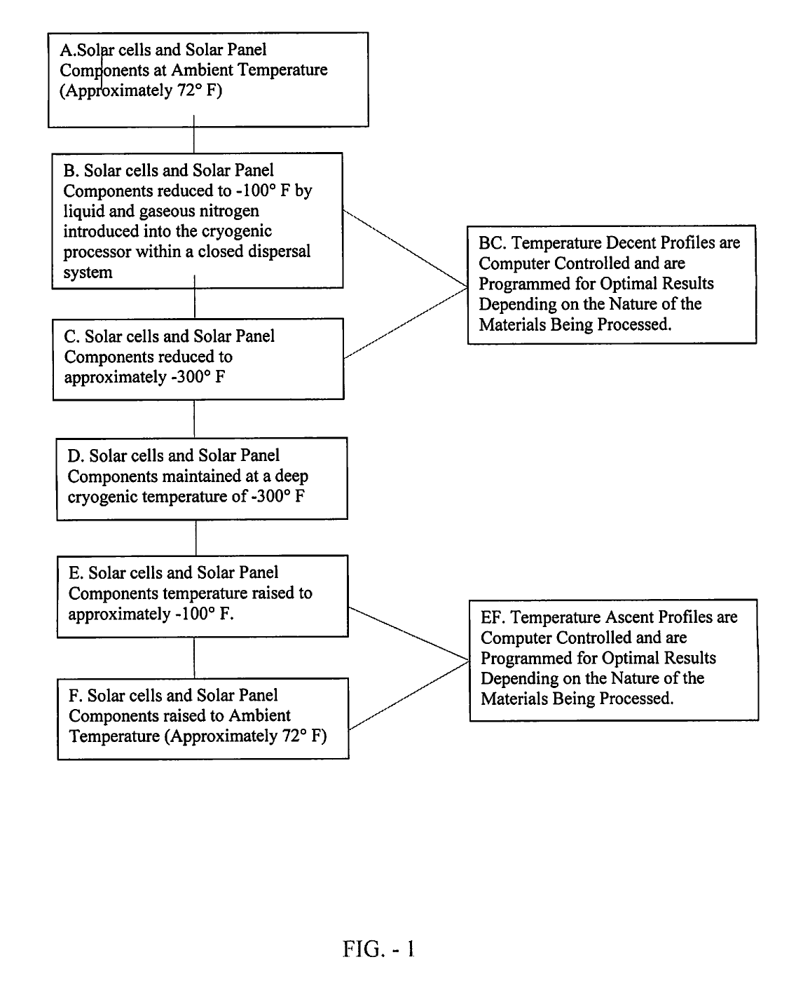

The gradual lowering of temperatures may be accomplished in several steps, the length of time the components are allowed to remain at a particular cryogenic temperature may also very and the gradual raising of temperatures also may be accomplished in several steps. The combinations of various ascent and descent steps as well as the length of time allowed for soaking at a cryogenic temperature are varied in accordance with the type of material that is being cryogenically processed. FIG. 1 illustrates the process in general terms. This can be seen, the solar cells and solar panel components are originally at ambient room temperature. They are then introduced into the cryogenic processor and the temperature of the components and cells are lowered to approximately −100° F. (1B) The reduction in temperature may occur in a smooth down the progression or may plateau at any point to continue the dissent. These are common referred to as steps. The progression and number of steps may depend upon the material being processed. The temperature is further reduced in a similar manner to deep cryogenic state at or near −300° F. Again, this may include several stepwise progressions in the lowering of the temperature. (1C) the components and cells are generally held in a deep cryogenic state for a bearing period of time at or near −300° F. (1D) After being held be held in a deep cryogenic state for a predetermined period of time, the components and cells are then gradually raised to approximately −100° F. Again a series of steps may be utilized in reaching this higher temperature. (1E) Finally, the cells and components are raised to ambient temperature. BC in FIG. 1 is considered the dissent profile which are computer-controlled and programmed for the optimum results depending upon the nature of the material being processed. BF in FIG. 1 is considered the ascent phase and the ascent profiles are again computer-controlled in a program for optimal results depending upon the nature of the materials being processed.

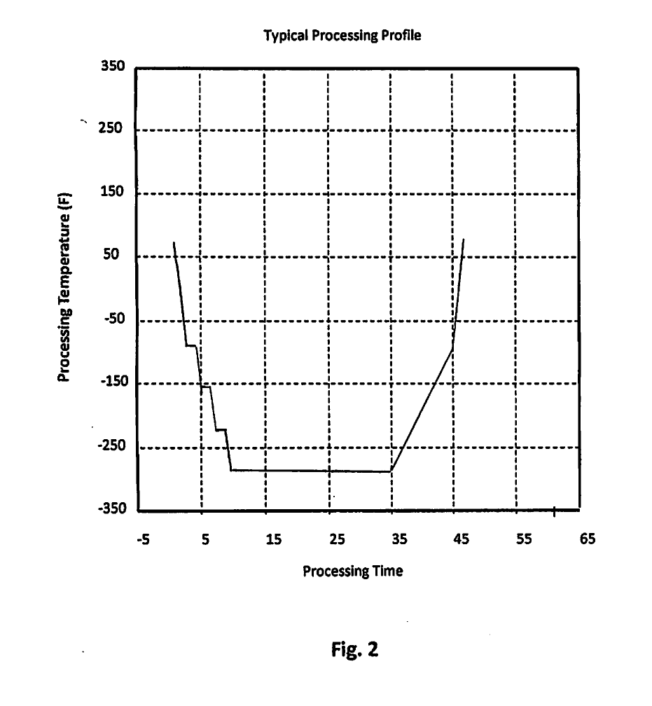

FIG. 2 shows the detailed steps of the of the method seen above. The x-axis represents processing time and the y-axis represents processing temperature. As can be seen the temperature dissent profile FIG. 1BC, begins at roughly room temperature and diminishes through a series of steps to the temperature at or close to −2° F. In this particular example of a typical processing profile the cells and components are soaked at a problem approximately a −300° F. of this temperature could be slightly greater or lesser depending upon the nature of the materials. FIG. 2 illustrates a profile in which the components are soaked for approximately 25 minutes in a deep trial state. This would represent step D in FIG. 1. In FIG. 2, the tempter line beginning at 35 minutes progresses upward finally ending at ambient temperature. This would represent in FIG. 1EF, the ascent profile.

### CONCLUSION

The method provides a means for improving the conductivity characteristics and lowered resistance characteristics of the various types of silicone metalloids and standard metal components within a solar panel. Although specific profiles have been illustrated in the ascent and descent and soaking phase of the cells and components, these should not be construed as limiting the scope of the invention but as merely providing illustrations of some preferred and useful embodiments currently employed. Many different profiles may be incorporated depending upon the nature of the cryogenic materials.

The scope of the appended claims, next appearing, should not be limited to these precise details but should given the scope of their legal equivalents.

I claim:

1. A method for increasing the photovoltaic output of solar cells by cryogenic treatment comprising the steps of:
a. providing a quantity of solar cells,
b. measuring the mass of said solar cells,
c. providing a cryogenic processor including a liquid or gaseous or gaseous nitrogen circulating system,
d. placing said solar cells within the cryogenic processor,
e. introducing liquid or gaseous nitrogen into the cryogenic processor's liquid or gaseous nitrogen circulating system,
f. lowering the temperature within the cryogenic processor which lowers the temperature of the solar cells to approximately −300° F. for a predetermined time,
g. holding the temperature of the solar cells at −300° F. for a predetermined time,
h. raising the temperature of the solar cells, over a predetermined time to ambient temperature,

2. The method of claim 1 wherein step (f) includes lowering the temperature of said solar cells over one or more steps, said steps being dependent upon the material that composes said solar cells.

3. The method of claim 1 wherein step (g) includes holding the solar cells at −300° F. for a predetermined time depending of the material that composes said solar cells.

4. The method of claim 1 wherein step (h) includes gradually raising the temperature of said quantity of solar cells in one or more steps said steps being dependent upon the material that composes said solar cells.

5. A method for treating solar panel components comprising the steps of:
a. providing a quantity of solar panel components,
b. measuring the mass of said solar panel components,
c. providing a cryogenic processor including a liquid or gaseous nitrogen circulating system,
d. placing said solar panel components within the cryogenic processor,
e. introducing liquid or gaseous nitrogen into the cryogenic processor's liquid or gaseous nitrogen circulating system,
f. lowering the temperature within the cryogenic processor which lowers the temperature of the solar panel components to approximately −300° F. for a predetermined time,
g. holding the temperature of the solar panel components at −300° F. for a predetermined time,
h. raising the temperature of the solar panel components, over a predetermined time to ambient temperature,

6. The method of claim 1 wherein step (f) includes lowering the temperature of said solar panel components over one or more steps, said steps being dependent upon the material that composes said solar panel components.

7. The method of claim 1 wherein step (g) includes holding the solar panel components at −300° F. for a predetermined time depending of the material that composes said solar panel components.
8. The method of claim 1 wherein step (h) includes gradually raising the temperature of said solar panel components in one or more steps said steps being dependent upon the material that composes said solar panel components.
